(19) United States
(12) Patent Application Publication
(10) Pub. No.: US 2023/0108475 A1
(43) Pub. Date: Apr. 6, 2023

(54) Thermal management techniques for high power integrated circuits operating in dry cryogenic environments

(71) Applicant: FormFactor, Inc., Livermore, CA (US)

(72) Inventor: Michael Snow, Erie, CO (US)

(21) Appl. No.: 17/958,102

(22) Filed: Sep. 30, 2022

Related U.S. Application Data
(60) Provisional application No. 63/252,057, filed on Oct. 4, 2021.

(51) Int. Cl. H01L 23/367; H01L 23/433; H01L 23/538; H01L 25/065; H01L 23/373; H01L 23/00

(52) U.S. Cl. CPC H01L 23/3677; H01L 23/4334; H01L 23/5384; H01L 25/0652; H01L 23/3736; H01L 24/02; H01L 2224/17181; H01L 2224/16227; H01L 2224/73253

(57) ABSTRACT

Improved heat sinking of electronic and/or photonic integrated circuit chips is provided by including thermal-only contacts on unused parts of the chip. The resulting chip can be bonded to a cold plate with a process that ensures that only the thermal contacts of the chip touch the cold plate, thereby avoiding problems caused by the cold plate creating electrical shorts of the chip. For example, the thermal contacts can be higher features than any electrical features on that side of the chip. This approach is expected to be especially useful for applications requiring low temperature operation (e.g., operation at 100K or less, preferably operation at 10 K or less).

### CROSS REFERENCE TO RELATED APPLICATIONS

This application claims priority from U.S. Provisional Patent Application 63/252,057 filed Oct. 4, 2021, which is incorporated herein by reference.

### GOVERNMENT SPONSORSHIP

None.

### FIELD OF THE INVENTION

This invention relates to thermal management of electronic and/or photonic circuits at cryogenic temperatures.

BACKGROUND

High power chips operating in cryogenic environments are difficult to keep cold. For their unique properties to work, they often must be kept below a specified temperature, e.g., 4 K. With a 3 K refrigeration source, it's difficult to heat sink more than few milliwatts. The challenge is not in providing enough refrigeration power, but in keeping the temperature difference between the chip and refrigerator sufficiently small. Particularly, the contact between the chip and the mount is typically not very thermally conductive. This is exacerbated by the materials properties at low temperatures. Many adhesive, gels, epoxies or other traditional thermal interface materials perform poorly at cryogenic temperatures. Heat sinking can be especially difficult for chips with electrical contacts on both sides, since in such cases there is no “back side” of the chip (i.e., having no electrical features on it) that can be used for heat sinking. Accordingly, it would be an advance in the art to provide improved thermal management at cryogenic temperatures.

### SUMMARY

Conventional ways to handle this problem are:

1) Dipping the chip and attendant wiring/apparatus in liquid helium, which can be very effective but is potentially complex and likely uses lots of helium, a precious unrenewable resource.

2) Clamping the die to a cold surface with a great force. This stresses the chip and may break it.

3) Using thermal interface compounds made for cryogenic use, for example copper-powder filled grease.

In contrast, the approach in this work is to provide thermal-only pads on the device which are then bump-bonded to a low CTE (coefficient of thermal expansion) heat spreader (e.g., Au/Pt plated Molybdenum). This heat spreader may then be clamped with great force or otherwise attached to the cryogenic platform, as it can be much less fragile than the chip itself.

This technique will provide better performance than these other techniques as it doesn't require liquid helium, and the key thermal interfaces are either high-force metal-to-metal or reflowed directly to the chip.

### BRIEF DESCRIPTION OF THE DRAWINGS

FIGS. 1A-B show exemplary chip configurations having through-chip vias.

FIGS. 2A-B show problems that can arise when heat sinking structures as in FIG. 1A.

FIGS. 3A-B schematically show results of relevant fabrication steps of an exemplary embodiment of the invention.

FIGS. 4A-B show the results of bonding the configuration of FIG. 3A to a cold plate.

FIG. 5A shows the result of integrating a photonic integrated circuit chip with the configuration of FIG. 4A.

FIG. 5B shows the result of bonding a second cold plate to the configuration of FIG. 5A.

### DETAILED DESCRIPTION

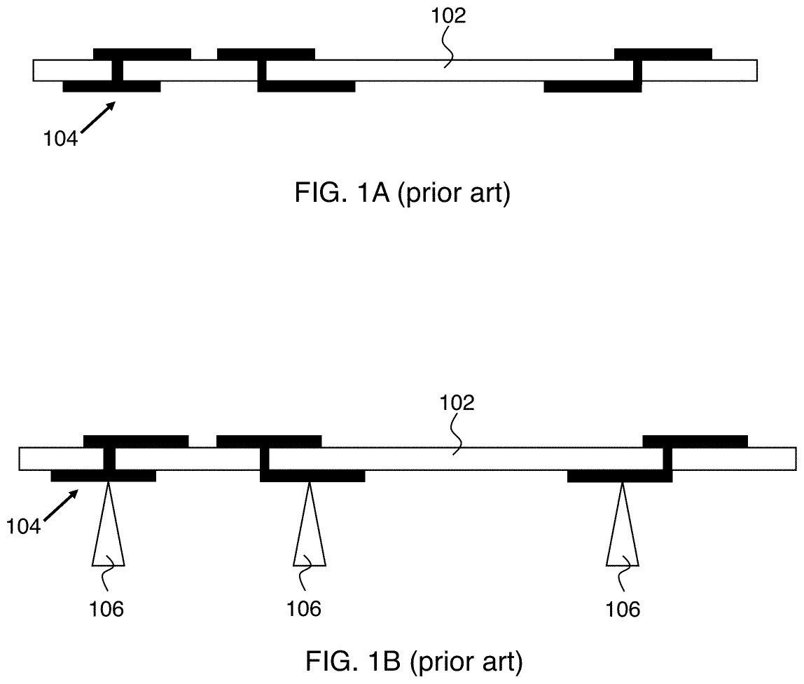

FIG. 1A schematically shows an exemplary electronic integrated circuit configuration. Here vias 104 (which can be through-silicon vias (TSVs)) pass through a device chip 102 to enable electrical connections on both sides of the device chip. For example, the upper side on FIG. 1A can be the device side and the lower side of FIG. 1A can be the redistribution layer (RDL) side. For simplicity, the functional circuitry of device chip 102 is not shown on the drawings, since that functional circuitry is generic.

FIG. 1B shows testing of the configuration of FIG. 1A by probing the redistribution layer side with probes 106 configured to make temporary electrical contact to the devices/circuits under test. Alternatively, in this and the following examples, probing can be done on the device side instead of the RDL side.

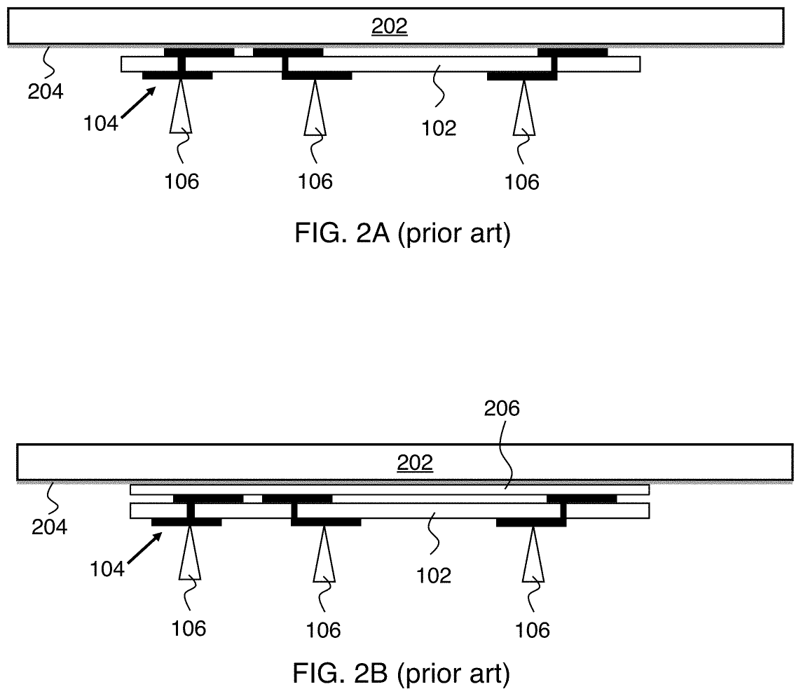

In order to better appreciate the difficulties associated with thermal management in such cases, FIGS. 2A-B show two conventional possibilities for heat sinking.

In the example of FIG. 2A, 202 is a cryostat cold plate, typically having a thermally (and often electrically) conductive surface coating 204. Direct contact between device chip 102 and cold plate 202 as shown on FIG. 2A will undesirably electrically short vias 104 to each other, as shown.

In the example of FIG. 2B, an electrically insulating plate 206 is disposed between device chip 102 and cold plate 202. This alleviates the electrical shorting problem of the configuration of FIG. 2A, but electrical insulators tend to be poor thermal conductors, so the resulting thermal performance is often inadequate. Cryogenic operation often demands the use of dry interfaces and hard materials, which further complicates the thermal design issues.

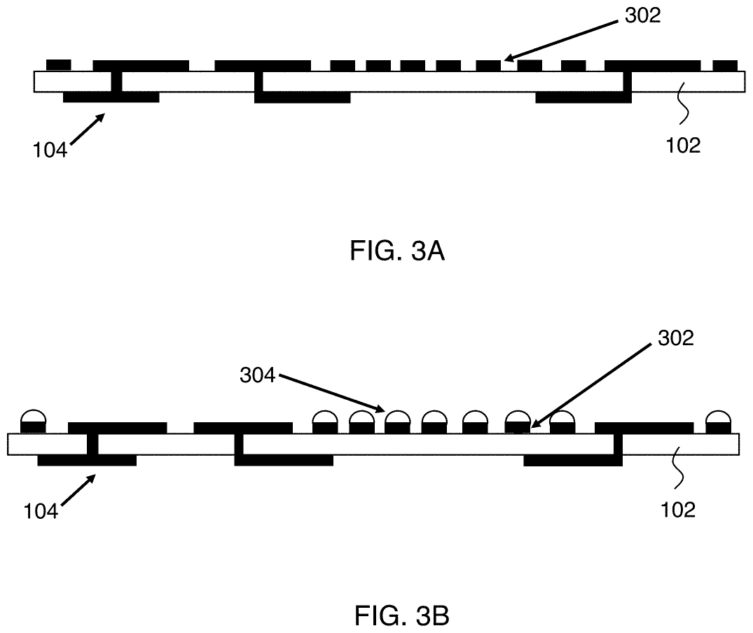

The main idea of this work is the use of thermal-only contacts to create heat flow paths from the chip to the cold plate. FIGS. 3A-B show an example of making such contacts. On FIG. 3A, thermal contact pads 302 are formed. This can be done as part of the same processing steps that define vias 104, or as part of another step of the complete fabrication sequence. After that, further material 304 (e.g., solder) can be selectively deposited on contact pads 302, but not on vias 104. Standard lithographic techniques can be used for this fabrication step.

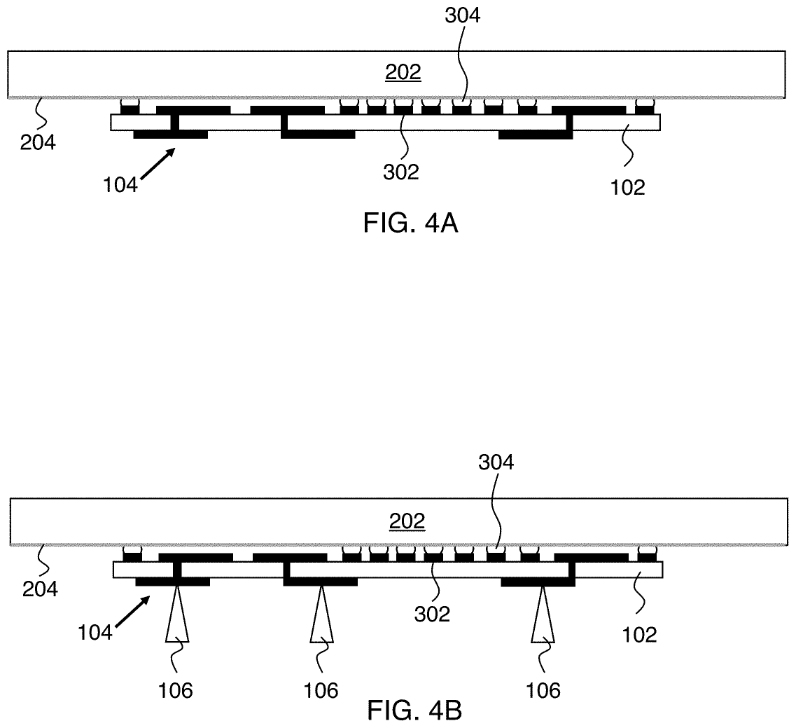

The resulting height difference in the features enables a heat sinking configuration as shown on FIG. 4A, which is obtained by bonding the configuration of FIG. 3B to a cold plate. The vertical gap between vias 104 and cold plate 202 (as shown on FIG. 4A) alleviates the shorting problem described in connection with FIG. 2A, while the thermal contacts can provide better thermal conductivity than an insulating plate 206 as on FIG. 2B.

Here the only direct contacts between chip 102 and cold plate 202 are via the thermal contacts 302/304. These thermal contacts are electrically isolated from the functional electrical circuits on chip 102. This is done either by having the thermal contacts completely electrically disconnected from the functional electrical circuits on chip 102, or electrically connected only to an electrical ground that is also connected to the functional electrical circuits on chip 102. In either case, the thermal contacts carry no electrical currents relevant to operation of the functional electrical circuits on chip 102. FIG. 4B shows probing of the configuration of FIG. 4A with probes 106.

Accordingly, an exemplary embodiment of the invention is a method of heat-sinking an electrical integrated circuit chip, the method including:

1) fabricating one or more first thermal contact pads (e.g., 302 on FIG. 4A) on the electrical integrated circuit chip (e.g., 102 on FIG. 4A) which are electrically isolated from functional circuitry of the electrical integrated circuit chip; and

2) bonding the electrical integrated circuit chip to a first heat spreading substrate (e.g., 202 on FIG. 4A), where the first thermal contact pads (e.g., 302 on FIG. 4A) are bonded to the first heat spreading substrate via first thermally conductive bonds (e.g., 304 on FIG. 4A).

The first heat spreading substrate can be selected from the group consisting of: molybdenum, tungsten, silicon, sapphire, and diamond. The first heat spreading substrate can be surface treated to improve bonding of the first thermally conductive bonds to the first heat spreading substrate. Such surface treating can include surface coating the first heat spreading substrate with a metal.

More generally, suitable heat spreader materials have low CTE mismatch (<0.1% integrated CTE mismatch from room temperature to 0K) and high thermal conductivity (>20 W/(m*K) at 4K), where the CTE mismatch is with respect to the electrical integrated circuit chip. Surface treatment of the heat spreader (e.g., sputtering gold onto it) can be used to improve the bonding of the thermally conductive bonds to the heat spreader. Other metals that could make sense as surface treatment interfaces include copper, indium, gold, silver, and platinum. In addition to a blanket interface film, it may be useful to pattern features like islands of wettability to ensure the bonds don't overly spread out, akin to solder mask on a printed circuit board.

The first heat spreading substrate can be thermally coupled to a cryogenic environment at 100 K or less. The present approach is expected to be especially useful for low temperature cryogenic applications, where device operation at 10K or less is required (e.g., operation at −4K or −1.5K). Note that temperature rise is a much more critical parameter at low cryogenic temperatures than at higher temperatures. For example, the difference between operation at 319 K vs. 315 K is almost certainly negligible, while the difference between operation at 8K vs. 4K is usually critical.

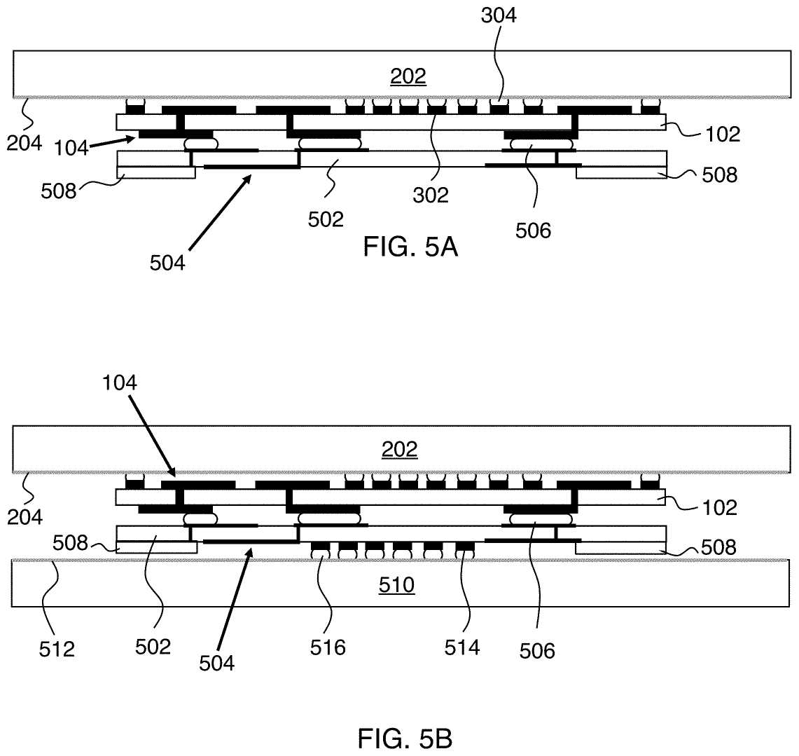

This approach can also be used in hybrid integration of electronic and photonic device chips. FIG. 5A shows a first example. Here a photonic chip 502 is bonded to electronic chip 302 via electrically conductive bonds 506. Photonic chip 502 can include features such as vias 504 and edge launch channels 508 (e.g., to couple to an optical waveguide or optical fiber).

Thus embodiments of the invention can further include bonding a photonic integrated circuit (e.g., 502 on FIG. 5A) to the electrical integrated circuit on a side of the electrical integrated circuit opposite the first heat spreading substrate.

In cases where photonic chip 502 dissipates significant heat, the configuration of FIG. 5B is preferred. Here photonic chip 502 includes thermal contacts 514/516 analogous to thermal contacts 302/304 as described above. A second cold plate 510 having a thermally conductive surface coating 512 serves as the heat sink for photonic chip 502. These cold plates may be held at different temperatures.

In this example, the corresponding fabrication method includes the steps of:

1) fabricating one or more second thermal contact pads (e.g., 514 on FIG. 5B) on the photonic integrated circuit chip which are electrically isolated from functional circuitry of the photonic integrated circuit chip.
2) bonding the photonic integrated circuit chip to a second heat spreading substrate (e.g., 510 on FIG. 5B), where the one or more second thermal contact pads (e.g., 514 on FIG. 5B) are bonded to the second heat spreading substrate via second thermally conductive bonds (e.g., 516 on FIG. 5B).

The second heat spreading substrate can be selected from the group consisting of: molybdenum, tungsten, silicon, sapphire, and diamond. The second heat spreading substrate can be surface treated to improve bonding of the second thermally conductive bonds to the second heat spreading substrate. Such surface treating can include surface coating the second heat spreading substrate with a metal. The second heat spreading substrate can be thermally coupled to a cryogenic environment at 100 K or less. Further details of the second heat spreading substrate are the same as described above in connection with the first heat spreading substrate.

Thermal management as described above can be used for both device testing and device packaging applications. For device testing, forceful clamping to a heat sink is one of the best ways to heat sink an electrical and/or photonic circuit. However, clamping of an device chip is likely to break the chip if it is done directly to the chip. The present approach provides the alternative of bonding the device chip to a cold plate where the cold plate can be sturdy enough to be clamped as needed for heat sinking. This is attractive for testing compared to approaches where a temporary thermal interface layer (e.g., using epoxy, solder or the like) is used for testing. For example, the present approach enables testing a high-power die, then easily unmounting it for further integration steps elsewhere.

Conventional bump-bonding approaches are suitable for use in embodiments of the invention. Suitable bump-bonding materials include but are not limited to: lead alloys, indium alloys and SAC (Sn—Ag—Cu) alloys.

1. A method of heat-sinking an electrical integrated circuit chip, the method comprising:
fabricating one or more first thermal contact pads on the electrical integrated circuit chip which are electrically isolated from functional circuitry of the electrical integrated circuit chip;
bonding the electrical integrated circuit chip to a first heat spreading substrate, wherein the one or more first thermal contact pads are bonded to the first heat spreading substrate via first thermally conductive bonds.

2. The method of claim 1, wherein the first heat spreading substrate is selected from the group consisting of:
molybdenum, tungsten, silicon, sapphire, and diamond.

3. The method of claim 1, further comprising surface treating the first heat spreading substrate to improve bonding of the first thermally conductive bonds to the first heat spreading substrate.

4. The method of claim 3, wherein the surface treating comprises surface coating the first heat spreading substrate with a metal.

5. The method of claim 1, wherein the first heat spreading substrate is thermally coupled to a cryogenic environment at 100 K or less.

6. The method of claim 1, further comprising bonding a photonic integrated circuit to the electrical integrated circuit on a side of the electrical integrated circuit opposite the first heat spreading substrate.

7. The method of claim 6, further comprising fabricating one or more second thermal contact pads on the photonic integrated circuit chip which are electrically isolated from functional circuitry of the photonic integrated circuit chip.

8. The method of claim 7, further comprising bonding the photonic integrated circuit chip to a second heat spreading substrate, wherein the one or more second thermal contact pads are bonded to the second heat spreading substrate via second thermally conductive bonds.

9. The method of claim 8, wherein the second heat spreading substrate is selected from the group consisting of: molybdenum, tungsten, silicon, sapphire, and diamond.

10. The method of claim 9, further comprising surface treating the second heat spreading substrate to improve bonding of the second thermally conductive bonds to the second heat spreading substrate.

11. The method of claim 10, wherein the surface treating comprises surface coating the second heat spreading substrate with a metal.

12. The method of claim 7, wherein the second heat spreading substrate is thermally coupled to a cryogenic environment at 100 K or less.
